(19) United States
(12) Patent Application Publication
(10) Pub. No.: US 2011/0089531 A1
(43) Pub. Date: Apr. 21, 2011

(54) Interposer Based Monolithic Microwave Integrate Circuit (iMMIC)

(75) Inventors: Christopher E. Hillman, Newbury Park, CA (US); Jonathan B. Hacker, Thousand Oaks, CA (US); Wonill Ha, Thousand Oaks, CA (US); Scott Newell, Moorpark, CA (US); Lan Tran, Van Nuys, CA (US)

(73) Assignee: Teledyne Scientific & Imaging, LLC

(21) Appl. No.: 12/896,786

(22) Filed: Oct. 1, 2010

Related U.S. Application Data
(60) Provisional application No. 61/252,547, filed on Oct. 16, 2009.

(51) Int. Cl. H01L 29/92; H01L 21/56

(52) U.S. Cl. 257/532; 438/127; 257/E21.502; 257/E29.343

(57) ABSTRACT

A system is disclosed for IC fabrication, including seating an integrated circuit (“IC”) having at least one contact into a recess of a silicon interposer substrate, applying an insulator in liquid form to fill portions of the recess not otherwise occupied by the IC and to cover a top surface of the IC and the silicon interposer substrate, introducing the insulator to a ramped environmental temperature, holding the environmental temperature at a reflow temperature to reflow the insulator and ramping down the environmental temperature to cure the insulator.

This application claims the benefit of U.S. Provisional Application No. 61/252,547 filed on Oct. 16, 2009.

### BACKGROUND OF THE INVENTION

1. Field of the Invention

The present invention relates generally to integrated circuit interposers and packaging, and more particularly to Monolithic Microwave Integrated Circuits (MMIC) that utilize interposers.

2. Description of the Related Art

Emerging 3D System-in-Chip packaging approaches require MMIC circuits to function properly when buried deep inside dielectric packages without signal degradation, circuit detuning, or signal leakage and cross-talk.

Power amplifier die area is dominated by the area used for impedance matching and power-combining networks. Matching networks require approximately 1-3 lines having a length of approximately λ_{d}/4 on both input and output, while N:1 power combiners require roughly N transmission lines also having a length of approximately λ/4. At 44 GHz, this represents a disadvantageously long 1 mm line length. For gallium nitride (GaN) high electron mobility transistor (HEMT) devices grown on silicon carbide (SiC) substrates, λ_{d}/4 is a disadvantageously long 0.73 mm at 40 GHz, exacerbated by the low dielectric constant of SiC compared to other III-V substrates such as GaAs and InP. These transmission line networks consume large areas of expensive heterostructure wafer material in traditional MMICs.

### SUMMARY OF THE INVENTION

A method of IC fabrication includes seating an integrated circuit (“IC”) having at least one contact into a recess of a silicon interposer substrate, applying an insulator in liquid form to fill portions of the recess not otherwise occupied by the IC and to cover a top surface of the IC and the silicon interposer substrate, introducing the insulator to a ramped environmental temperature, holding the environmental temperature at a reflow temperature to reflow the insulator, and ramping down the environmental temperature to cure the insulator.

An apparatus is disclosed that includes a substrate having a recess, an integrated circuit (“IC”) seated in the recess, the IC having a plurality of contacts, a benzocyclobutene (“BCB”) layer filling portions of the recess not otherwise occupied by the IC and extending onto a face of the substrate, at least one via extending through the BCB layer to communicate with the contact and a patterned metal layer in communication with the contact through the BCB layer. The patterned metal layer is a first metal interconnect layer that is in communication with the IC through the BCB layer.

### BRIEF DESCRIPTION OF THE DRAWINGS

The components in the figures are not necessarily to scale, emphasis instead being placed upon illustrating the principals of the invention. Like reference numerals designate corresponding parts throughout the different views.

FIG. 1 is a cross section of one embodiment of an iMMIC, with a recess to receive an MMIC extending entirely through a silicon interposer substrate;

FIG. 2-19 are cross sectional views illustrating fabrication steps in one implementation of the iMMIC of FIG. 1;

FIG. 20 is a cross section of an embodiment of an iMMIC, with a recess to receive an MMIC seated on a heat sink extending to an opposite side of the silicon interposer substrate;

FIG. 21 is a cross section of an embodiment of an iMMIC, with a recess to receive an MMIC in thermal communication with thermal vias that extend to an opposite side of the silicon interposer substrate;

FIG. 22 is a top plan view of one embodiment of an interposer-based MMIC (iMMIC);

FIG. 23 is a cross sectional view an embodiment illustrating ICs extending beyond the top surface of an interposer;

FIG. 24 is a cross sectional view an embodiment illustrating ICs that are flush with the top surface of an interposer;

FIG. 25 is a cross sectional view an embodiment illustrating ICs that are seated below the top surface of an interposer;

FIG. 26 is a cross sectional view of an embodiment of an interposer that has recesses of different depths to seat respective ICs;

FIG. 27 is a top plan view of a wafer comprising multiple iMMICs in accordance with an exemplary embodiment of the invention;

FIG. 28 is a flow chart illustrating one embodiment of a method of forming an iMMIC;

FIG. 29 is a flow chart illustrating a method of seating an MMIC in a recess of a silicon interposer using a BCB layer as an interlayer dielectric; and

FIG. 30 is a graph of temperature verses time for curing the BCB layer in the flow chart illustrated in FIG. 29.

### DETAILED DESCRIPTION OF THE PREFERRED EMBODIMENTS

A method for fabricating an integrated circuit interposer, in accordance with one embodiment, includes seating an IC in a recess of a silicon interposer substrate and providing a low stress Benzocyclobutene (“BCB”) film in the recess and over both the seated IC and silicon interposer substrate. The novel low stress process enables thicker BCB films than previously obtained in the art in a process suitable for circuit level batch fabrication.

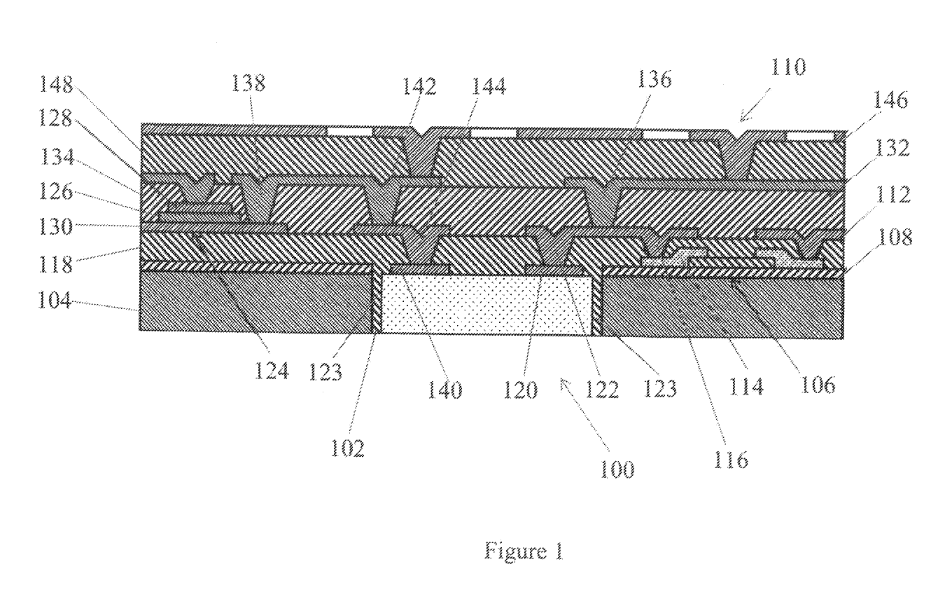

FIG. 1 illustrates one embodiment of an MMIC 100 fully seated in a recess 102 of an interposer substrate, preferably a silicon interposer substrate 104, with the recess 102 preferably extending entirely through the silicon interposer substrate. A device such as a thin film resistor (TFR) 106 preferably sits on the silicon interposer substrate 104 through a dielectric insulator layer 108 as part of a power combining and matching network (not shown). In alternative embodiments, the recess 102 may extend only partially through the silicon interposer substrate 104 with the MMIC 100 extending above or below a top surface of the silicon interposer substrate 104. The MMIC 100 may also be another IC unrelated to microwave applications for seating in the silicon interposer substrate 104. The MMIC 100, silicon interposer substrate 104 and power combining and matching network (not shown) establish one embodiment of an iMMIC 110.

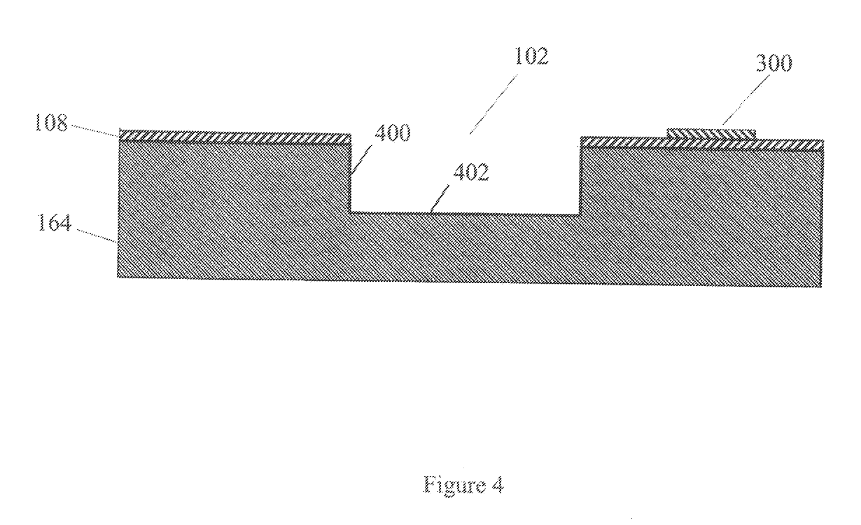

A first patterned metal layer 112 is in communication with a TFR contact 114 of the TFR 106 through a TFR via 116 that extends through a benzocyclobutene (BCB) layer 118. The first patterned metal layer 112 is also in communication with an IC contact 120 through an IC via 122 that extends through the BCB layer 118. Narrow channels 123 are established between the MMIC 100 and the sides (see FIG. 4) of the recess 102, with the BCB layer 118 extending down into and filling the channels 123 of the recess 102 not otherwise occupied by the MMIC 100 to fixedly couple the MMIC 100 to the silicon interposer substrate 104.

A capacitor 124 is defined by a capacitor dielectric layer 126 sandwiched between a depositing metal plate 128 and a capacitor plate portion 130 of the first patterned metal layer 112. A second patterned metal layer 132 is spaced apart from the first patterned metal layer 112 by a second BCB layer 134, and is in communication with the first patterned layer 114 through an interlayer via 136. The capacitor plate portion 130 is in communication with the second patterned metal layer 132 through a capacitor via 138 to enable further communication to a second IC contact 140 through the vias 142 and 144. A third patterned metal layer 146 may be deposited on a third BCB layer 148 that is formed over the second patterned metal and BCB layers (132, 134).

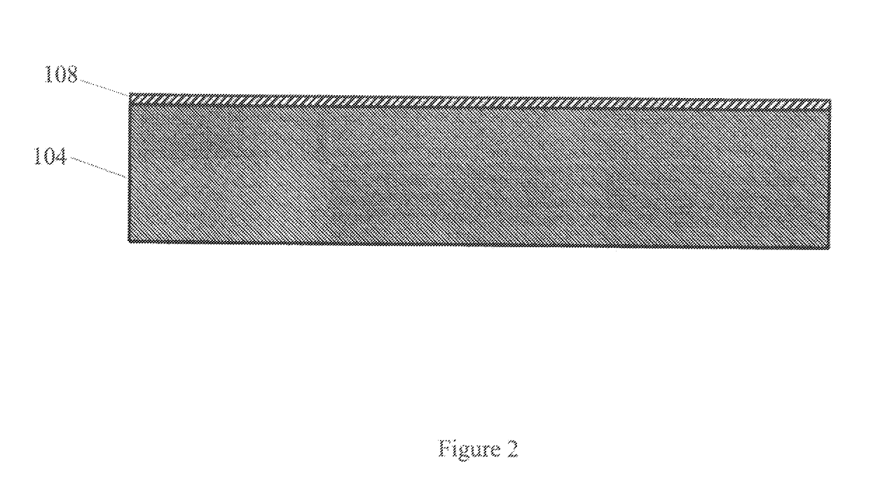

FIGS. 2 through 19 illustrate fabrication steps in one implementation of the iMMIC of FIG. 1. FIG. 2 illustrates a first step showing the dielectric insulator layer 108 deposited on the silicon interposer substrate 104. The composition of the silicon interposer substrate 104 is not critical, although use of lithography grade wafers can be advantageous. The preferred embodiment utilizes low resistivity silicon (e.g. wafers having a resistivity of less than 8000 ohm-cm). Although alternative methods may be used, it is contemplated that use of plasma-enhanced chemical vapor deposition (PECVD) to deposit the dielectric insulator layer 108 on the silicon interposer substrate 104 will in some instances be particularly advantageous as may be the use of silicon dioxide (Si02) as dielectric insulator layer 108.

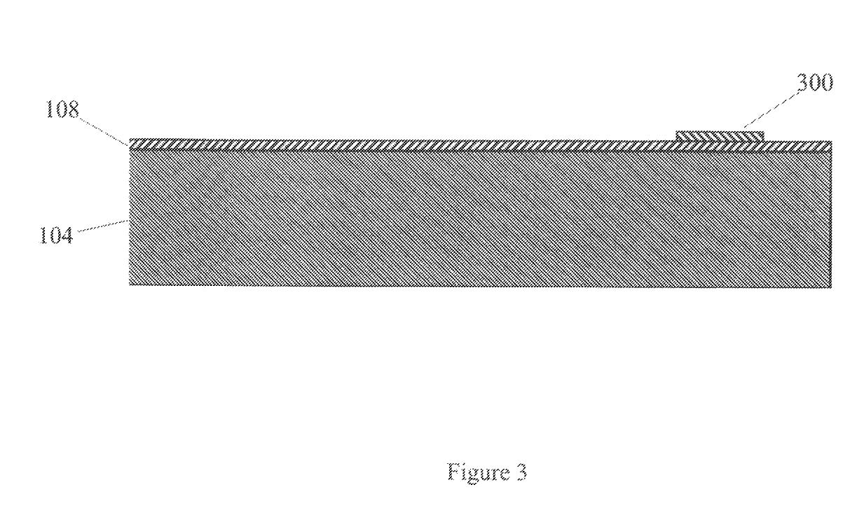

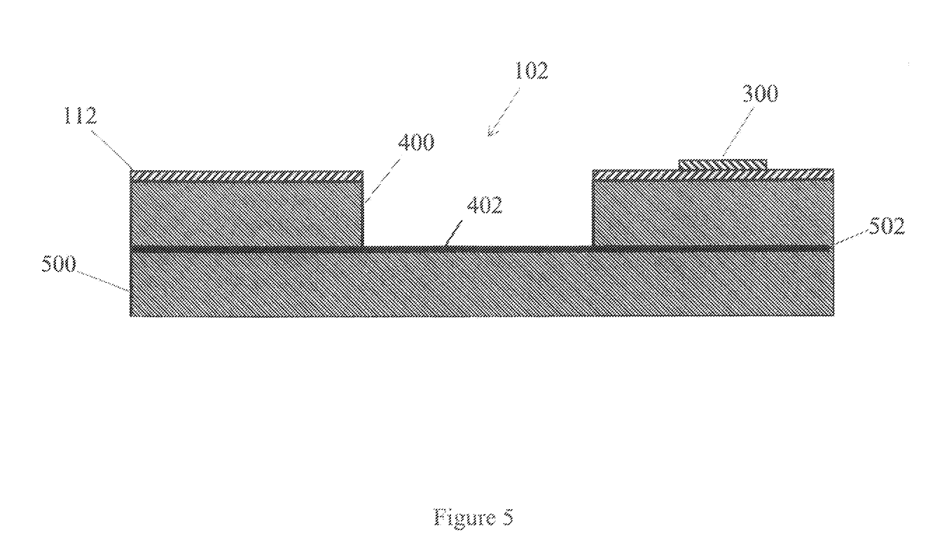

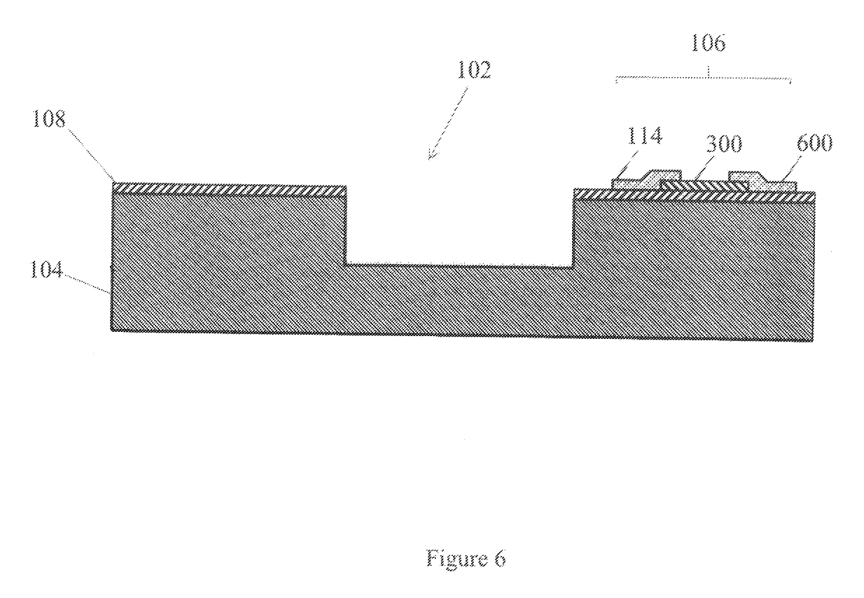

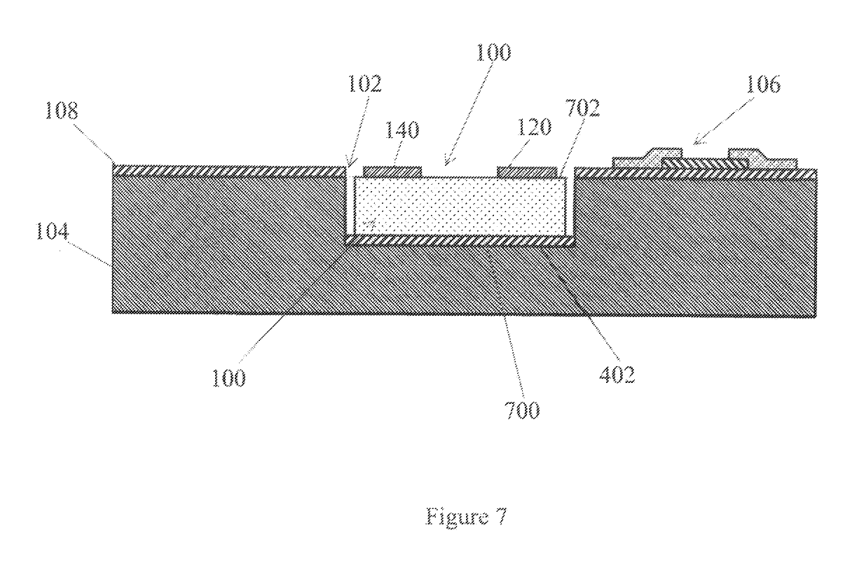

In FIG. 3, a thin film resistor material 300 is formed on the dielectric insulator layer 108, preferably through use of submicron photolithography. In FIG. 4, the fabrication illustrated in FIG. 3 is modified by etching through the dielectric insulator layer 108, preferably through the use of deep reactive-ion etching (DRIE), one or more recesses, such as recess 102 having sides 400 and a bottom 402 in the silicon interposer substrate 104. In an alternative embodiment, etching the recess(es) 102 can be facilitated by utilizing a silicon interposer substrate 500 having one or more oxide stop layers 502 as shown in FIG. 5. In FIG. 6, the structure of FIG. 4 (or FIG. 5) is modified by depositing a patterned metal layer (M0) on the thin film resistor material 300 and adjacent portions of the dielectric layer 108 to form the TFR contact 114 and a second TFR contact 600 to form the TFR 106. The TFR contacts (114, 600) are preferably formed of gold, but may be formed with a metallic alloy, other metal or conductive material. In FIG. 7, the structure illustrated in FIG. 6 is modified by dispensing an adhesive 700, preferably epoxy, onto the bottom 402 of the recess 102, and positioning the MMIC 100 (having body 702 and first and second IC contacts 120, 140) in the recess 102 where it is bonded into the recess 102 by the adhesive 700. It is important to note that in other embodiments the MMIC 100 may be an IC or other component. In some embodiments, first and second IC contacts (120, 140) may have a width of approximately 50 to 104 microns.

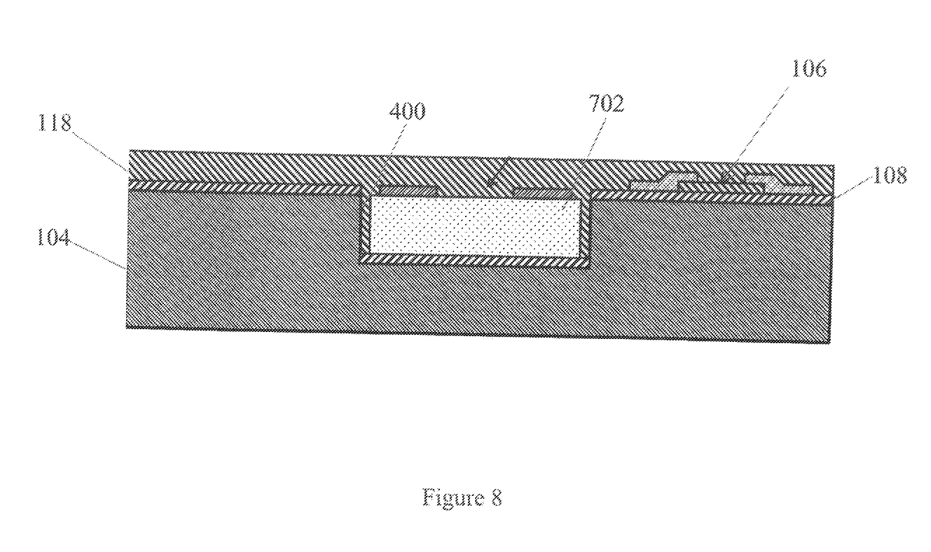

In FIG. 8, the structure of FIG. 7 is further modified by depositing and planarizing a first interlayer dielectric (ILD 1), preferably the BCB layer 118. The BCB layer 118 is preferably poured onto the dielectric insulator layer 108, or may be spun, spray coated, or deposited in some other fashion onto dielectric insulator layer 108 and over TFR 106. It is preferred that the material of the ILD 1 (and layers 134 and 148 of FIG. 1) be applied in such a manner that it provides a smooth, void free surface over the MMIC 100, TFR 106, and any other structures formed on dielectric insulator layer 108 so as to facilitate formation of IC scale structures on dielectric layer 106. As an example, if BCB is applied by pouring, any gaps between the body 702 and sides 400 should be sufficiently filled and void-free after curing, and the layer sufficiently thick such that the upper surface of layer 108 can be sufficiently smoothed by lapping. In an alternative embodiment, a 2-4 micron layer of BCB may be deposited to fill any irregularities in the lapped surface. Then, the BCB may be etched back 2-4 microns leaving a lithographically flat and scratch free surface.

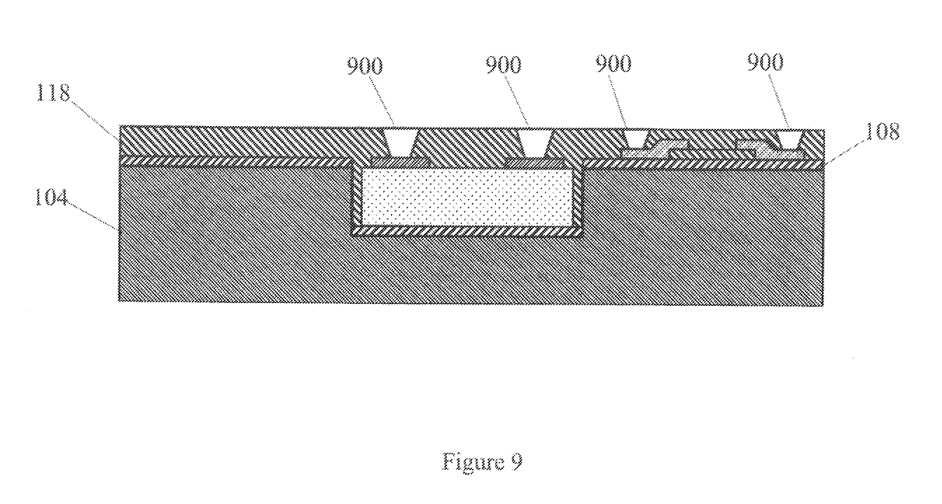

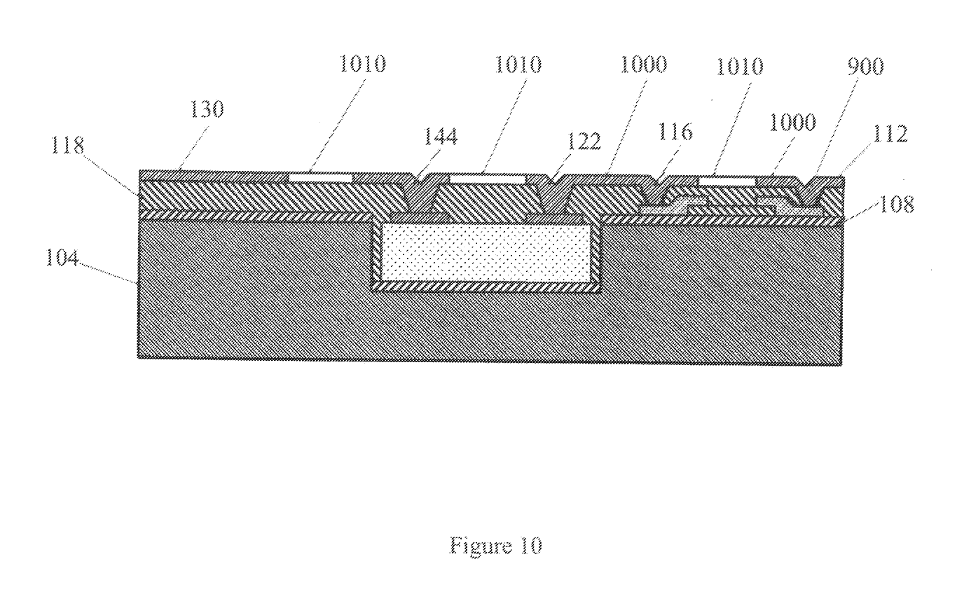

In FIG. 9, the subassembly of FIG. 8 is further modified by opening holes for IC via 122, via 144, TFR via 116 and a second TFR via 900 in the BCB layer 118. In FIG. 10, the fabrication of FIG. 9 is further modified by depositing the first patterned metal layer 112 (preferably gold) (M1) on dielectric insulator layer 108 (ILD 1) and to form ILD 1 via holes 900. In FIG. 10, the first patterned metal layer 112 comprises conductive portions (pads, traces, etc.) 1000, ILD 1 open areas 1010 exposing portions of dielectric layer 108 (ILD 1), portions filling the vias holes to establish the TFR via 116, IC via 122, miscellaneous other vias (144, 900), and the capacitor plate portion 130. It is contemplated that the elements of patterned metal layer 112 (and layers 132 and 146) are advantageously IC scale (submicron pitch and line width) with layer 112 advantageously having a thickness of 0.1 to 3 microns.

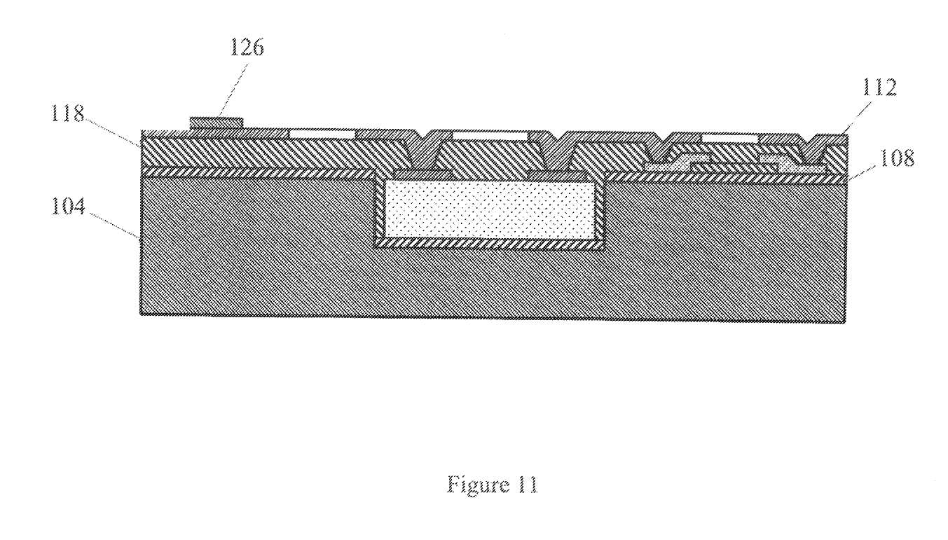

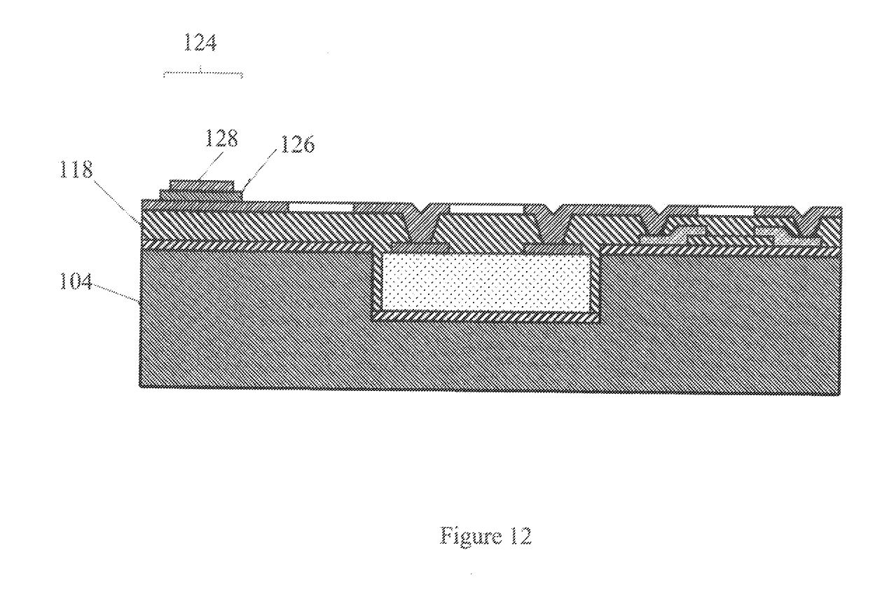

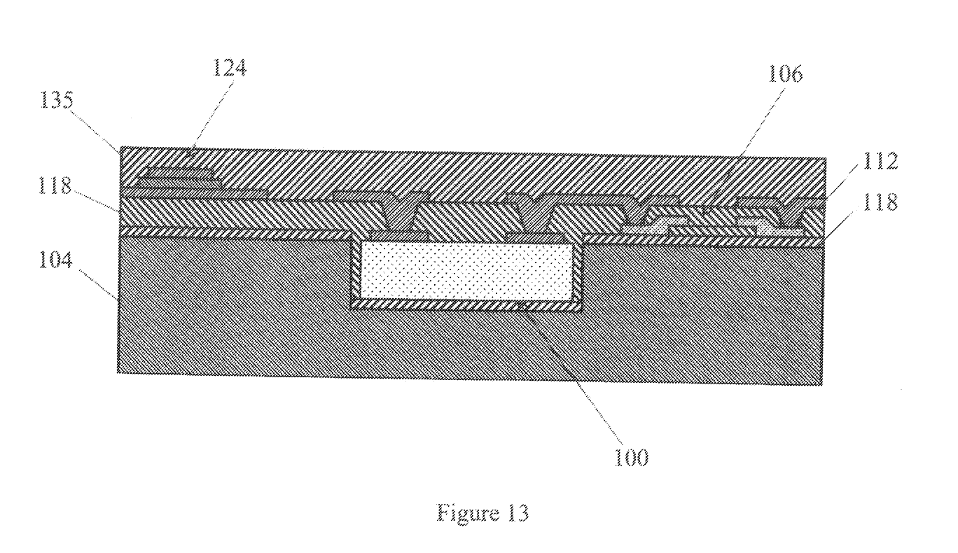

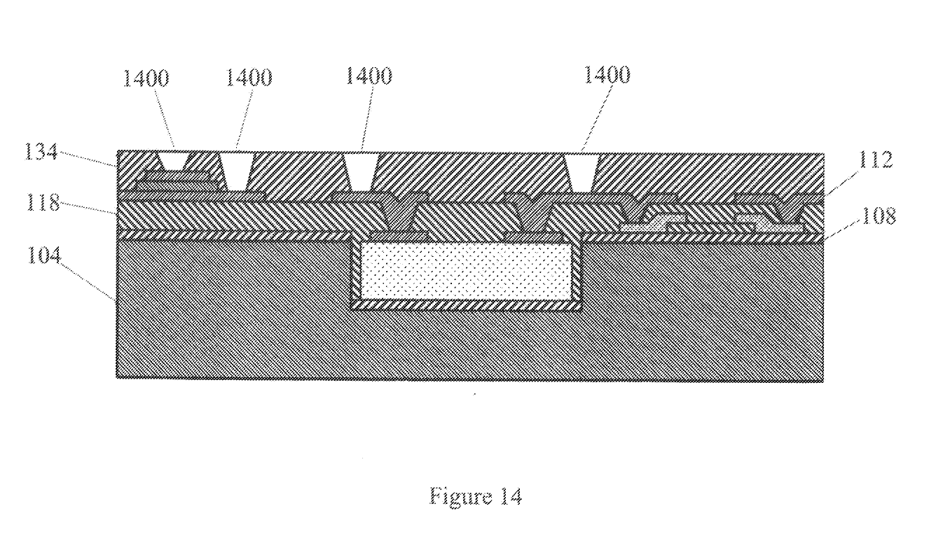

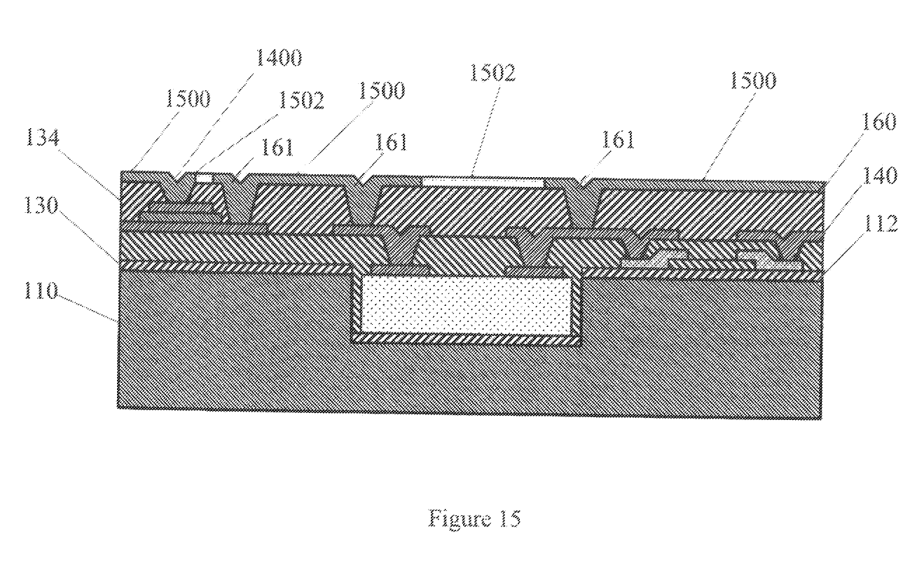

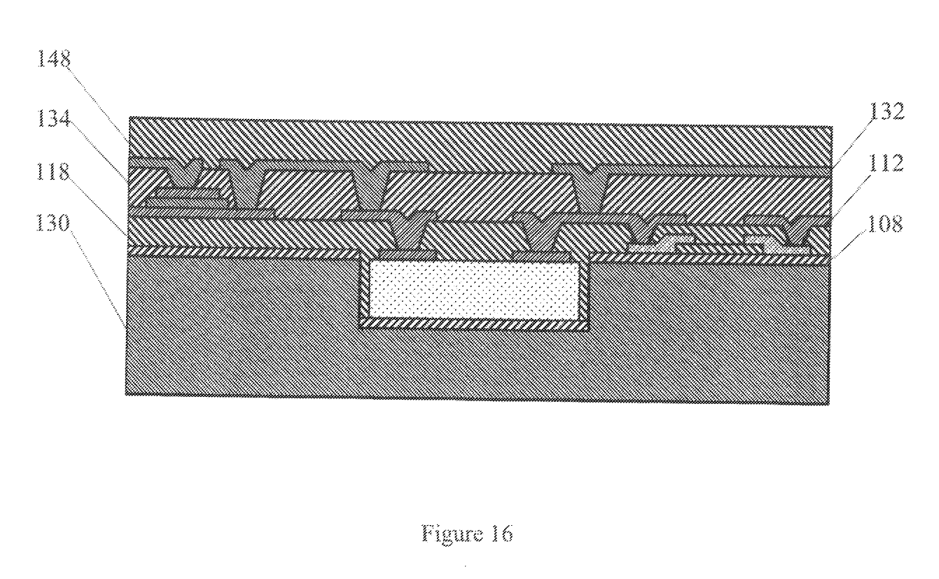

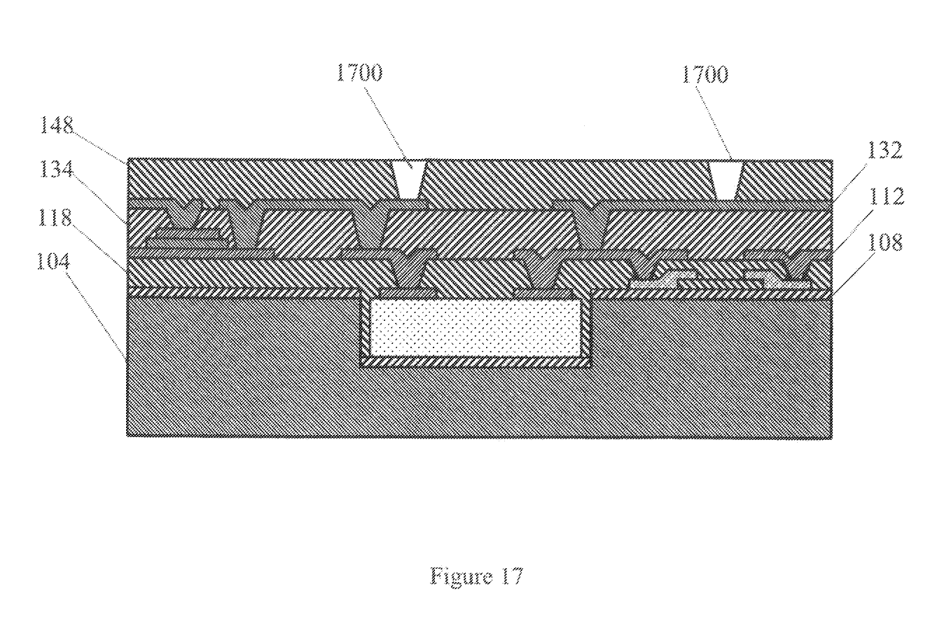

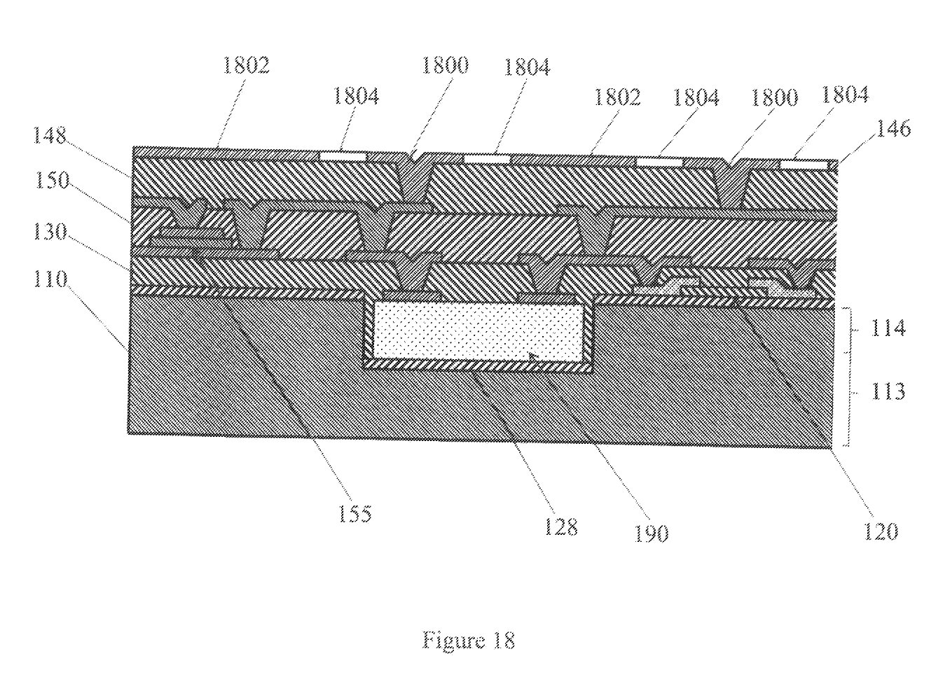

In FIG. 11, fabrication of the structure illustrated in FIG. 10 is continued by depositing and patterning the capacitor dielectric layer 126 (e.g. silicon nitride, SiNx) on the first patterned metal layer 112. In FIG. 12, the structure of FIG. 11 is further modified by patterning and depositing metal plate 128 (CAPM) on the capacitor dielectric layer 126 to form capacitor 124. In FIG. 13, the fabrication of the structure illustrated in FIG. 12 is further modified by depositing and planarizing a second BCB layer (ILD 2) 134. Fabrication continues in FIG. 14 by opening ILD 2 via holes 1400 in the second BCB layer (ILD 2) 134. In FIG. 15, second patterned metal layer 132 (M2) is formed on the second BCB layer 134 (ILD 2) and to form the vias (1400, 138, 142, 136). In FIG. 15, the second patterned metal layer 132 forms conductive portions (pads, traces, etc.) 1500, ILD 2 open areas 1502 exposing portions of BCB layer 150 (ILD 2), and the process fills the ILD 2 via holes (see FIG. 14) to form vias 1400, 138, 142, 136. In FIG. 16, the fabrication of the structure of FIG. 15 is continued by depositing and planarizing the third BCB layer 148 (ILD 3). In FIG. 17, ILD 3 via holes 1700 are opened in the third BCB layer 148 (ILD 3), with FIG. 18 illustrating the patterned metal layer 146 (M3) deposited on the third BCB layer 148 (ILD 3) and in the ILD 2 via holes 1700 (see FIG. 17) to form ILD 3 vias 1800. In FIG. 18, the third patterned metal layer 146 includes ILD 3 conductive portions (pads, traces, etc.) 1802, and ILD 3 open areas 1804 exposing portions of the third BCB layer 148 (ILD 3).

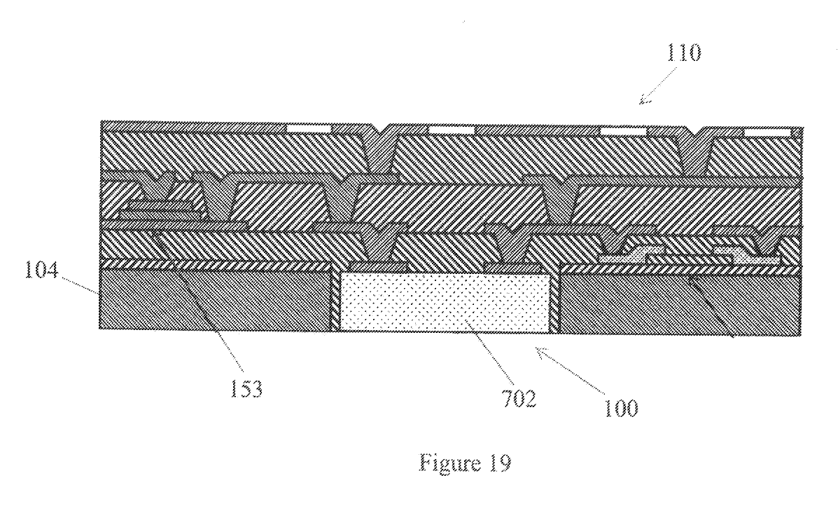

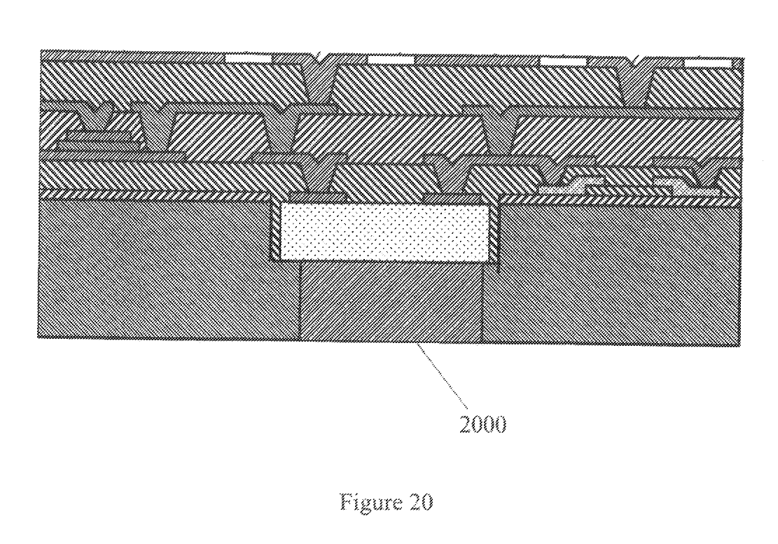

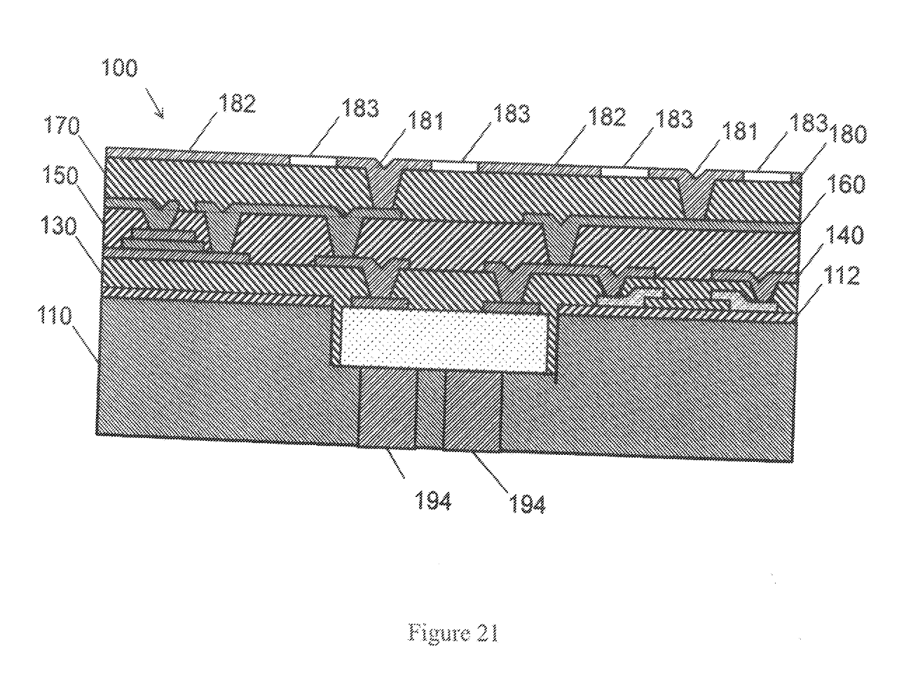

FIGS. 19, 20, and 21 illustrate alternative embodiments of iMMIC 110. In FIG. 19, a bottom portion of the silicon interposer substrate 104, adhesive 700 (see FIG. 7) and potentially a portion of the body 702 of MMIC 100 is removed to expose MMIC 100 within the iMMIC 110. Alternatively, as illustrated in FIGS. 20 and 21, the interposer substrate 104 may be left substantially intact but modified to include a heat sink (see FIG. 2000), thermal vias 2100 (see FIG. 2100), or some other heat transfer mechanism for moving thermal energy out of MMIC 100.

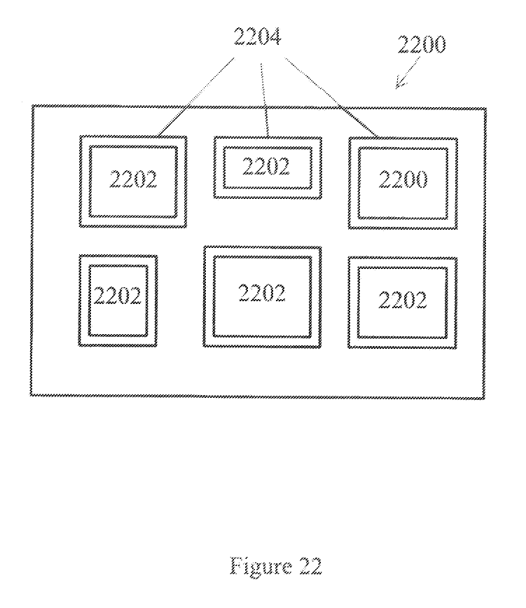

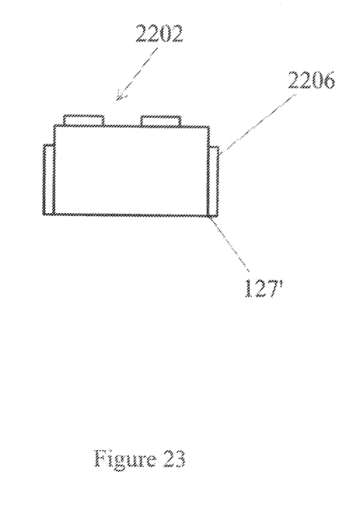

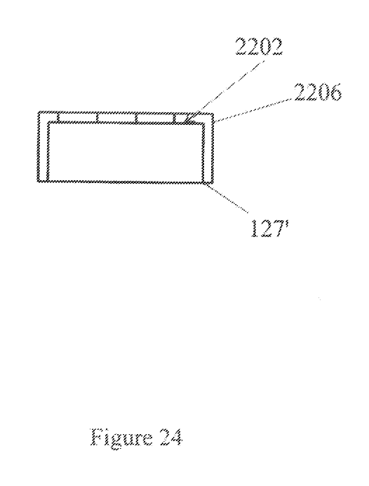

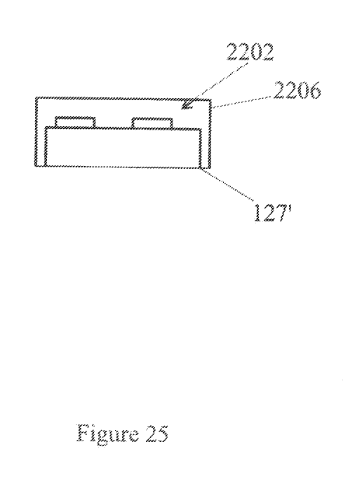

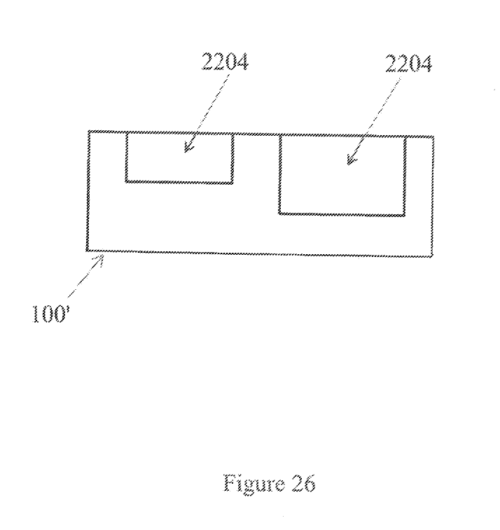

As shown in FIG. 22, an iMMIC 2200 may comprise multiple MMICs or other ICS 2202 in recesses 2204. As shown in FIGS. 22, 23, 24, and 25, ICs 2202 may vary in dimension and in some instances may extend out of recesses 2204 (i.e. be taller than the sides 2206), may have contacts that are coplanar with the top of recesses 2204 (i.e. sides 2206 having a height that matches that of the IC 2200), and/or may be substantially shorter than the sides 2206. Moreover, recesses 2204 may vary in depth as shown in FIG. 26 as well as in x-y dimensions as shown in FIG. 22.

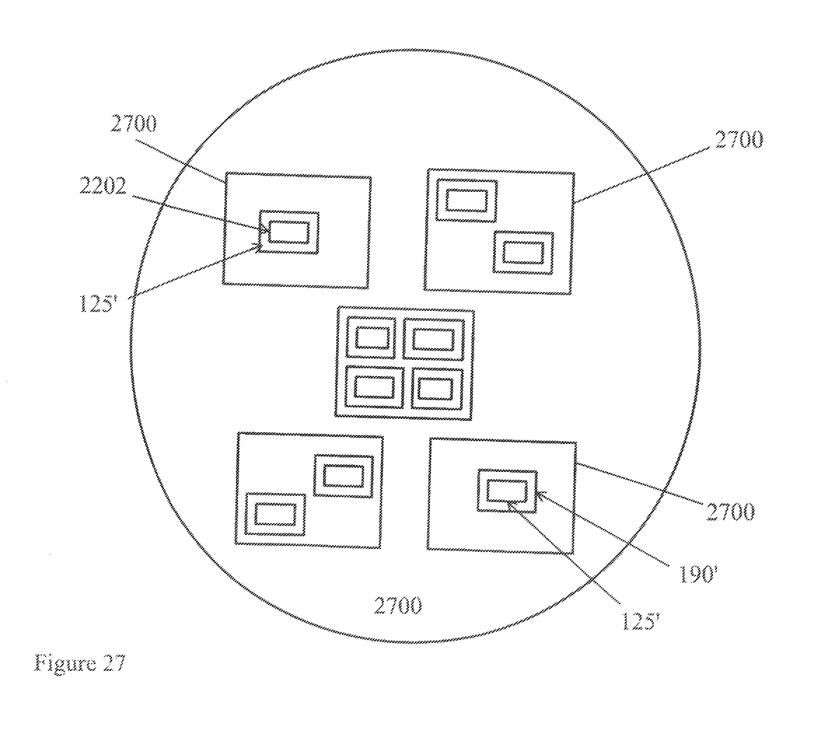

FIG. 27 illustrates a wafer 2700 comprising multiple iMMICs 2200 in recesses 2204 formed in subsections 2700.

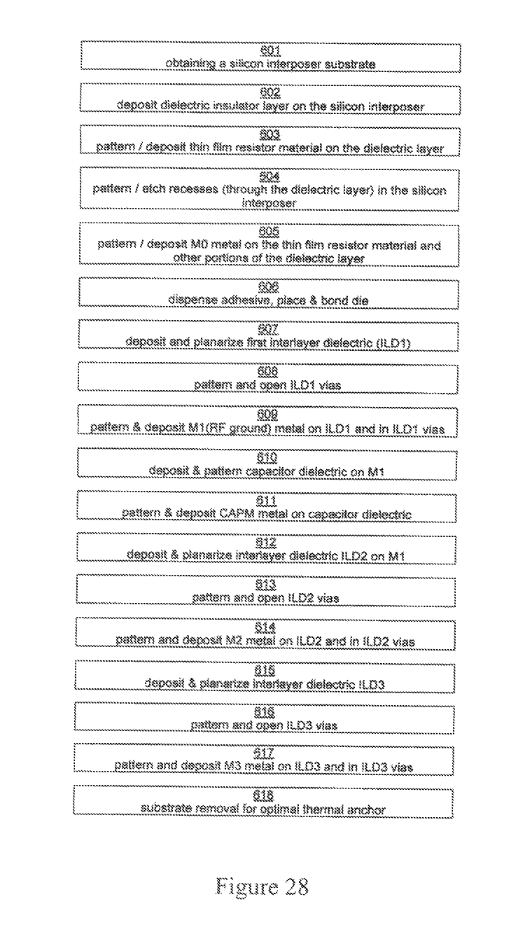

FIG. 28 illustrates one embodiment of a process for forming an iMMIC. The steps include obtaining a silicon interposer substrate (block 2800) and depositing a dielectric insulator layer on the silicon interposer substrate (block 2802). A thin film resistor material is patterned/deposited on the dielectric layer (block 2803) and recess(es) are patterned and etched (through the dielectric layer) in the silicon interposer (block 2804). An M0 metal is patterned and preferably deposited on the thin film resistor material and other portions of the dielectric layer (block 2805). Adhesive or other die attach material such as epoxy, BCB, or solder is dispensed in the recess, and a die is placed and bonded into the recess (block 2806). A first interlayer dielectric (ILD 1) is provided and planarized (block 2807), and ILD 1 vias are patterned and opened (block 2808). An M1 (RF ground) metal is patterned and deposited on ILD 1 and in ILD 1 vias (block 2809). A capacitor dielectric is deposited and patterned on M1 (block 2810), and a CAPM metal patterned and deposited on a capacitor dielectric (block 2811). An interlayer dielectric ILD 2 is deposited on M1 and then planarized (block 2812). ILD 2 vias are patterned and opened (block 2813) and then M2 metal is patterned and deposited on ILD 2 and in ILD 2 vias (block 2814). An interlayer dielectric ILD 3 is deposited and planarized (block 2815), and then ILD 3 vias (block 2816) are patterned opened. M3 metal is patterned and deposited on ILD 3 and in ILD 3 vias (block 2817). Preferably, a bottom portion of the substrate is removed for optimal thermal anchor (block 2818).

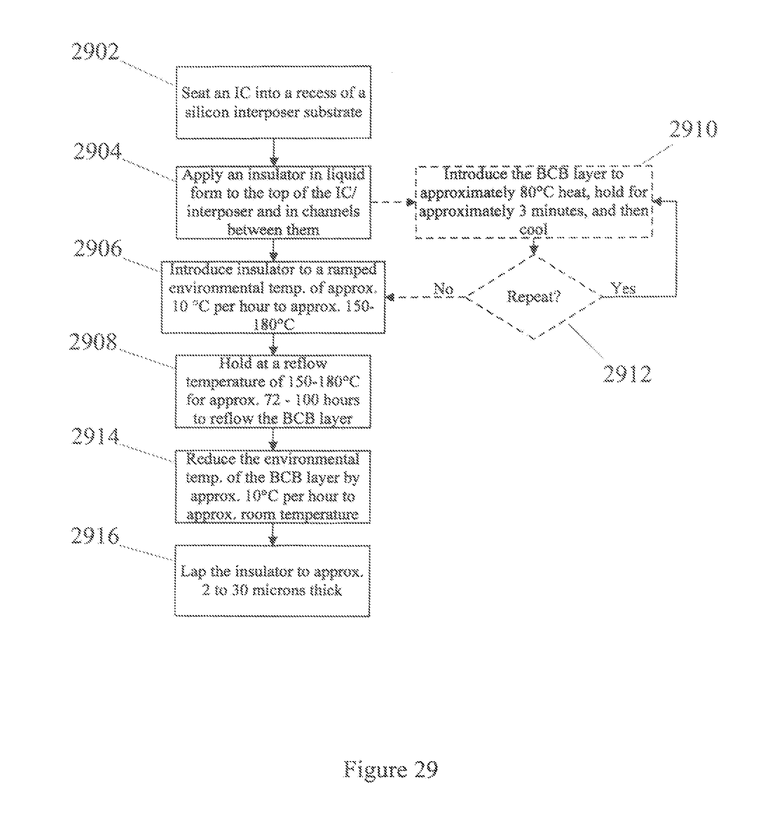

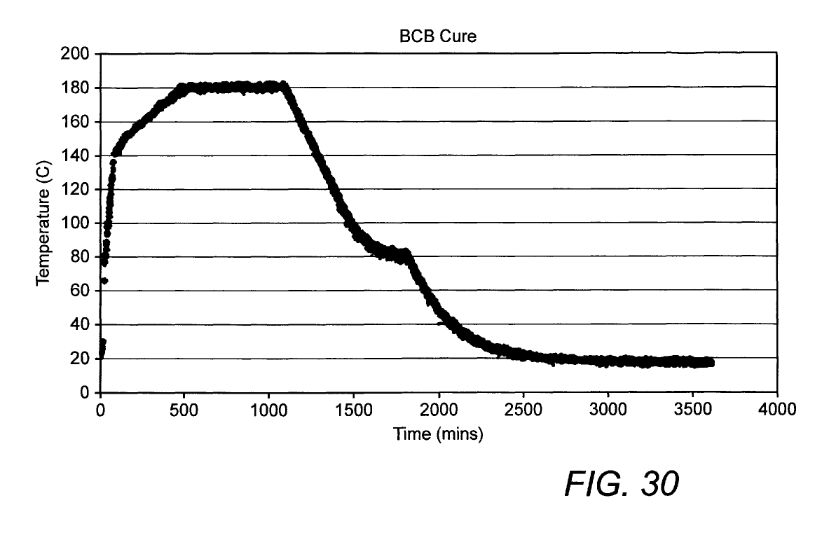

FIG. 29 expands on the process illustrated in FIG. 28, and illustrates one embodiment of a process to place and bond a die into the recess, as well as to provide the interlayer dielectric (ILD 1) that is preferably a benzocyclobutene (BCB) layer (blocks 2806, 2807). An IC is seated into a recess of a silicon interposer substrate (block 2902) and an insulator in liquid form, preferably the BCB layer, is applied such as by pouring onto the top of the IC and interposer and in the channels between them (block 2904). The BDB layer (ILD 1) is introduced to a ramped environmental temperature, preferably approximately 10° C. per hour up to a reflow temperature of approximately 150° C. to 180° C. (block 2906). The environmental temperature is held at the reflow temperature for approximately 72-100 hours to reflow the BCB layer (ILD 1) (block 2908). In an alternative embodiment, before introducing the BCB layer (ILD 1) to the reflow temperature, it is introduced to a gas extraction temperature, preferably 80° C. and held for approximately 3 minutes, and then cooled (block 2910). In this alternative embodiment, the gas extraction cycling may be repeated several times to remove gas that is otherwise trapped in the BCB layer (ILD 1) and in the channels, in particular (block 2912). After the reflow temperature is attained and held for 72-100 hours (block 2908), the environmental temperature for the BCB layer (ILD 1) is reduced by approximately 10° C. per hour to arrive at room temperature (block 2914). BDB layer (ILD 1) may then be thinned, preferably by lapping, to a thickness of between 2 and 30 microns (block 2916).

The iMMIC approach allows space-consuming passive structures to be moved off of the expensive (GaN or other III-V) epitaxial surface, and onto the adjacent low-cost silicon interposer, without compromising the electrical and thermal performance like that of more conventional wirebond or flip-chip hybrid architectures. Consequently, the iMMIC performs like a traditional MMIC, but with the flexibility and cost savings of a hybrid design.

Yield of iMMIC power amplifiers can be improved if only known-good-die are used to form the multiple cells that are power-combined together to form the final iMMIC amplifier. Assuming a reasonable 90% yield for a 40 GHz GaN power cell with a 320 μm gate width, then an iMMIC using prescreened unit cells will yield twice as many functional amplifiers compared to a monolithic 8 cell amplifier, whose predicted yield will be only 43%. Taken together, these two improvements will demonstrate cost savings on the order of 20 times compared to a conventional GaN MMIC of the same performance.

### Express and Implied Limitations

For any method described herein as including certain steps, unless the method is expressly limited, the steps may be performed in some other order than they are listed herein, and may be preceded, followed, and/or separated by steps not described herein. Moreover, unless expressly limited, any such step may be replaced by one or more steps not described herein and/or may comprise multiple sub-steps not described herein.

As used herein, terms that might each be interpreted as describing something having a unitary structure should, unless explicitly described as being limited to having a unitary structure (i.e. formed as a single piece such as by casting, molding, etc.), be interpreted as including combinations formed from a plurality of unitary items (i.e. items that each have a unitary structure) and/or sub-combinations. Such terms include but are not necessarily limited to the following: part, piece, element, component, and member. As such, an element (part, piece, etc.) may be a combination of elements and/or sub-combinations.

As used herein, terms that might be interpreted as describing a combination of unitary items and/or sub-combinations should, unless explicitly described as being limited to having a nonunitary structure, be interpreted as including unitary items. Such terms include but are not necessarily limited to the following: assembly, structure, and system. As such, an assembly (structure, etc.) may have a unitary structure.

Any item, whether unitary or non-unitary, may comprise any material or combination of materials unless explicitly limited to a particular material or combination of materials.

It is important to note that simply describing something as having a unitary or non-unitary structure, or as comprising a particular material or combination of materials is not an explicit limitation. To be an explicit limitation, the term “must” or the term “require” (or a variation thereof) must be used such as in the phrase “element A must have a unitary structure”, or in the phrase “assembly B is required to be have a non-unitary structure”. Any description that appears to be limiting (such as “A is” and “B has”), but is not explicitly limiting (i.e. including the term “must” or the term “require”), should be interpreted as being non-limiting.

The phrases “consisting of” and “consisting essentially of”, if used in a claim of the numbered list of claims included herein, should be interpreted as being expressly limiting. The phrase “consisting of” should be interpreted as a closed term that includes any recited elements or steps and excludes any un-recited elements or steps. When the phrase “consists of” appears in a clause of the body of a claim, rather than immediately following the preamble, it limits only the element set forth in that clause; other elements are not excluded from the claim as a whole. For example, a claim to a combination consisting of A+B does not cover the combination A+B+C. In contrast, the term “comprising” (which is synonymous with “including,” “containing,” or “characterized by”) should be interpreted as an open term that includes any recited elements but that does not exclude any un-recited elements. For example, a claim to a combination comprising A+B covers a combination having A+B+C. The phrase “consisting essentially of” should be interpreted as a phrase that is part open and part closed, and that includes any recited elements but excludes additional un-recited elements which would affect the basic and novel characteristic(s) of the claimed apparatus or method. As such, a claim to a combination consisting essentially of A+B would cover a combination of A+B+C if C does not affect the basic and novel characteristic(s) of the claimed apparatus or method.

### Additional Embodiments

The embodiments of the present invention described herein comprise multiple novel features with each described embodiment including either a single such feature or a combination of such features. Other contemplated embodiments include all combinations of one or more such novel features not explicitly described herein as such combinations are readily discernable from the embodiments described. In light of the various contemplated embodiments, the present invention can be characterized in a number of ways with the following paragraphs providing examples of some such characterizations.

In some embodiments, the embodiments comprises a method of rf packaging and combining of integrated circuits and discrete active devices (die) and/or the resulting assemblies of packaged ICS and devices. In some instances: (a) the die is mounted in precision etched recesses in low-resistivity silicon substrate; (b) the method comprises forming a planar layer over a recessed die by using an ILD layer to form a smooth void free surface above the recessed die; (c) the method includes forming multiple layers of conductive traces on inter-layer dielectric (ILD) such as BCB; (d) the method includes forming transverse transmission lines formed using conductive traces on ILD; (e) the method comprises forming transmission line fields contained above a substrate in ILD layers by conductive layer between the substrate and the ILD; (f) the method permits low-resistivity (conductive) silicon substrate for mode suppression; (g) the method supports multiple transmission line configurations such as microstrip, stripline, and CPW; (h) impedance controlled transmission lines can be maintained to the die pads; (i) impedance controlled interconnects can be arbitrarily realized between any die and die pads; (j) optional lithographically processed resistors, capacitors, and inductors (passive elements) may be combined with the conductive trace interconnects; (k) the method is compatible with integrated circuit processing techniques for submicron lithographic tolerances of conductive traces and passive elements; (l) the method is compatible with compact vertical capacitors; (m) the method is compatible with thru silicon vias for vertical signal and power transfer; and (n) a silicon substrate/interposer can be optionally a fabricated CMOS wafer.

What is claimed is:

1. A method of IC fabrication, comprising:
seating an integrated circuit (“IC”) having at least one contact into a recess of a silicon interposer substrate;
applying an insulator in liquid form to fill portions of the recess not otherwise occupied by the IC and to cover a top surface of the IC and the silicon interposer substrate;
introducing the insulator to a ramped environmental temperature;
holding the environmental temperature at a reflow temperature to reflow the insulator;
ramping down the environmental temperature to cure the insulator.

2. The method of claim 1, further comprising:
introducing the insulator to a gas extraction temperature, holding at such gas extraction temperature for a gas extraction period to allow formed gas to migrate out of the recess, and then cooling the insulator to approximately room temperature, each prior to the introducing the insulator in liquid form to the ramped environmental temperature step.

3. The method of claim 1, further comprising:
lapping the insulator to a thickness of approximately 2 to 30 microns.

4. The method of claim 3, further comprising:
applying an insulator in liquid form after said lapping step to a layer thickness of approximately 2-4 microns to fill irregularities in a lapped surface of said insulator; and
etching said insulator after said lapping and said applying an insulator steps back approximately 2-4 microns.

5. The method of claim 1, further comprising:
opening a plurality of a vias in the insulator to expose at least one of the at least one contact.

6. The method of claim 5, further comprising:
depositing patterned metal onto the insulator to form conductive portions.

7. A method of IC fabrication, comprising:
seating an integrated circuit (“IC”) having at least one contact into a recess of a substrate, the recess having side walls to establish a channel between the substrate and the seated IC;
applying a benzocyclobutene (BCB) layer to portions of said recess not otherwise occupied by the IC and to cover a top surface of the IC and the substrate;
introducing the BCB layer to a ramped environmental temperature of approximately 10° C. per hour to approximately 150-180° C.;
holding the BCB layer at approximately 150-180° C. for approximately 72-100 hours to reflow the BCB for reduction of gaseous voids in the channel;
reducing the environmental temperature of the BCB layer by approximately 10° C. per hour to approximately room temperature to cure the BCB.

8. The method of 7, further comprising:
introducing the BCB layer to approximately 80° C. heat, holding at such temperature for approximately 3 minutes, and then cooling the BCB layer to approximately room temperature, each prior to the introducing the BCB to the ramped environmental temperature step.

9. The method of claim 8, further comprising:
repeating the introducing the BCB layer to approximately 80° C. heat step a plurality of times before the introducing the BCB layer to the ramped environmental temperature step.

10. The method of claim 8, further comprising:
lapping the BCB layer to a thickness of approximately 2 to 30 microns.

11. The method of claim 7, further comprising:
opening a plurality of a vias in the BCB layer to expose at least one of the at least one contact.

12. The method of claim 11, further comprising:
depositing a patterned metal layer onto the BCB layer to form conductive portions.

13. The method of claim 12, further comprising:
depositing capacitor dielectric material; and
depositing metal on the capacitor dielectric material to form a capacitor.

14. The method according to claim 7, wherein the seating an IC having at least one contact into a recess of a substrate comprises seating the IC into a silicon interposer substrate.

15. An apparatus, comprising:
a substrate having a recess;
an integrated circuit (“IC”) seated in the recess, the IC having a plurality of contacts;
a benzocyclobutene (“BCB”) layer filling portions of the recess not otherwise occupied by the IC and extending onto a face of the substrate;
at least one via extending through the BCB layer to communicate with the contact; and
a patterned metal layer in communication with the contact through the BCB layer;
wherein the patterned metal layer is a first metal interconnect layer that is in communication with the IC through the BCB layer.

16. The apparatus of claim 15, further comprising:
a thin film resistor (TFR) on said substrate; and
at least one TFR via extending through the BCB layer to communication with the TFR through a TFR contact, said TFR via in communication with at least one of said plurality of contacts on the IC through the first metal interconnect layer.

17. The apparatus of claim 15, further comprising:
a capacitor dielectric layer formed on a capacitor plate portion of the patterned metal layer; and
a depositing metal plate on the capacitor dielectric layer;
wherein the capacitor dielectric layer between the depositing metal plate and the capacitor plate portion of the patterned metal layer form a capacitor.

18. The apparatus of claim 17, further comprising:
a second BCB layer formed on said patterned metal layer;
a second patterned metal layer formed on said second BCB layer; and
at least one capacitor via extending through the second BCB layer to communication with the capacitor plate portion of the patterned metal layer, said capacitor via in communication with at least one of said plurality of contacts on the IC through the first metal interconnect layer.
wherein the portion of the patterned metal layer
wherein said the portion of the patterned metal layer is in communication with the contact through vias.

19. An apparatus, comprising:
an integrated circuit (IC) seated in a recess of a silicon interposer substrate, the IC having at least one contact;
a dielectric insulator layer encapsulating at least three sides of the IC and a top surface of the silicon interposer substrate;
a metal via extending through the dielectric insulator layer and contacting at least one of the at least one contact; and
a capacitor on the dielectric insulator layer and in communication with the at least one of the plurality of contacts through a patterned metal layer on the dielectric insulator layer.

20. The apparatus of claim 19, wherein the dielectric insulator layer comprises benzocyclobutene (“BCB”).

21. The apparatus of claim 19, further comprising:
a die attach material between said IC and said recess to couple said IC to said recess.
